(19) United States
(12) Patent Application Publication
(10) Pub. No.: US 2004/0208062 A1
(43) Pub. Date: Oct. 21, 2004

(54) Nonvolatile memory cell array

(76) Inventor: Wen-Ying Wen, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/414,089

(22) Filed: Apr. 16, 2003

(51) Int. Cl. G11C 11/34

(52) U.S. Cl. 365/185.28

(57) ABSTRACT

A nonvolatile memory cell array is formed by arranging a plurality of storage memory cells in array. A plurality of bit lines are used to electrically connect memory cells on transversal rows. A plurality of word lines are used to electrically connect memory cells on longitudinal columns. The combination of each word line and each bit line represents a specific storage memory cell. The source of the transistor in each storage memory cell is electrically connected to a corresponding word line, while the gate and drain thereof are electrically together connected to a corresponding bit line. Therefore, the area of memory cell can be effectively shrunk, and the integration density of memory cell can also be effectively enhanced.

### FIELD OF THE INVENTION

The present invention relates to a semiconductor device structure and, more particularly, to a nonvolatile memory cell array structure.

### BACKGROUND OF THE INVENTION

Memories are semiconductor devices for storing data. If data stored in a memory will not disappear even the power supply is interrupt, the memory is called a nonvolatile memory. The nonvolatile memory can be further divided into read-only memory (ROM), mask read-only memory (mask ROM), programmable ROM (PROM), erasable programmable ROM (EPROM), electrically erasable programmable ROM (EEPROM), and flash memory.

As shown in FIG. 1, a conventional nonvolatile memory cell array is formed by arranging a plurality of storage memory cells in array. Memory cells in the same column or row are series connected with a common lead. The lead connecting a transversal row is called a word line, while the lead connecting a longitudinal column is called a bit line. The gate of the transistor in each memory cell is electrically connected to a corresponding word line, the drain thereof is connected to a corresponding bit line, and the source thereof is series connected to a source voltage (V_{SS}) or ground. Because each transistor requires three contacts, the area of the unit memory cell is larger, and the integration density of memory cell cannot be effectively enhanced, hence limiting the development.

Accordingly, the present invention aims to propose a novel nonvolatile memory cell array to resolve the problems in the prior art.

### SUMMARY OF THE INVENTION

The primary object of the present invention is to provide a nonvolatile memory cell array, whereby the area of memory cell can be effectively shrunk, and the integration density of memory cell can also be effectively enhanced.

Another object of the present invention is to provide a nonvolatile memory cell array having high-density memory cells, whereby the planar area occupied by a memory cell can be effectively shrunk to conform to the requirement of high memory density.

To achieve the above objects, a nonvolatile memory cell array of the present invention is formed by arranging a plurality of storage memory cells in array. A plurality of bit lines are used to electrically connect memory cells on transversal rows. A plurality of word lines are used to electrically connect memory cells on longitudinal columns. The combination of each word line and each bit line represents a specific storage memory cell. The source of the transistor in each storage memory cell is electrically connected to a corresponding word line, while the gate and drain thereof are electrically together connected to a corresponding bit line.

The various objects and advantages of the present invention will be more readily understood from the following detailed description when read in conjunction with the appended drawings, in which:

### BRIEF DESCRIPTION OF THE DRAWINGS

FIG. 1 is a circuit structure diagram of a conventional nonvolatile memory cell array;

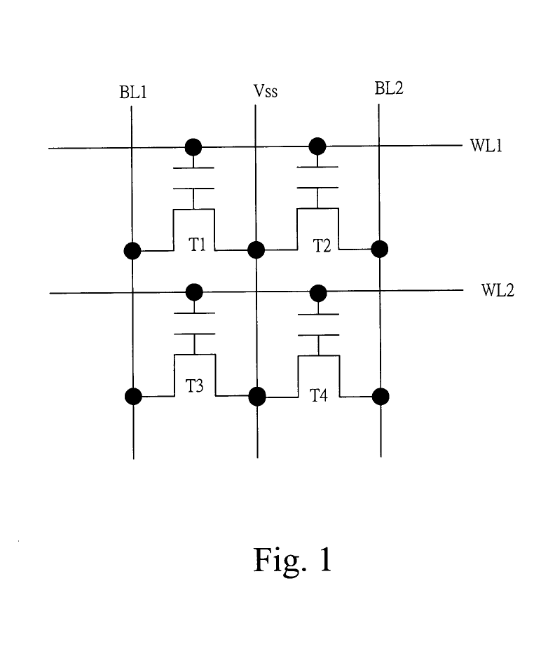

FIG. 2 is a circuit structure diagram of a memory cell array of the present invention;

FIG. 3 is a voltage versus current curve of a storage memory cell of the present invention; and

FIG. 4 is a program/erase versus time curve of a storage memory cell of the present invention.

### DETAILED DESCRIPTION OF THE PREFERRED EMBODIMENTS

In the present invention, the control gate and drain of each transistor are series connected together to a corresponding bit line so that each transistor only requires two contacts. Therefore, the number of contacts of transistor can be reduced, and the area of the unit memory cell can be relatively shrunk, hence enhancing the integration density of memory cell.

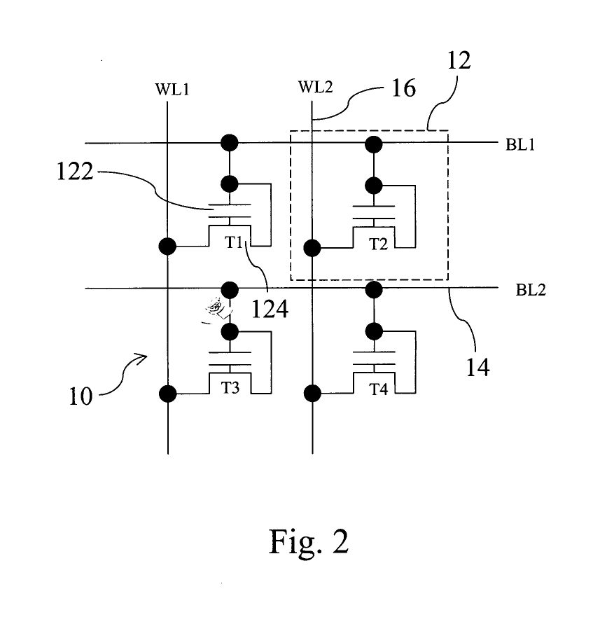

As shown in FIG. 2, a nonvolatile memory cell array 10 is formed by arranging a plurality of storage memory cells in array. The combination of each column and each row represents the address of a specific memory cell. Memory cells on the same column or row are series connected using a common lead. The lead connecting memory cells 12 on a transversal row is called a bit line 14, while the lead connecting memory cells on a longitudinal column is called a word line 16. Each storage memory cell 12 is composed of a capacitor 122 and a transistor 124. The source (S) of the transistor 124 is electrically connected to a corresponding word line 16, and the gate (G) and drain (D) thereof are series connected together to a corresponding bit line 14.

For the operation of the nonvolatile memory cell array of the present invention, a source voltage V_{S}, a drain voltage V_{D} and a gate voltage V_{G} are applied to the source, drain and gate of a memory cell 12, respectively. Because the drain and gate are series connected together, the gate voltage equals the drain voltage. It is only necessary to apply voltages on the source and gate to perform read, program and erase of memory cell.

When performing read to the transistor T2 in FIG. 2, the voltage applied to a first bit line (BL1) of the gate is a operation voltage (V_{CC}), the voltage applied to a first word line (WL1) of the source is a operation voltage (V_{CC}) or floating, and the voltage applied to a second word line (WL2) and a second bit line (BL2) is zero.

When performing program to the transistor T2 in FIG. 2 by means of hot electron channel injection, the voltage applied to the first bit line (BL1) of the gate is a high voltage (V_{PP}), the voltage applied to the first word line (WL1) of the source is floating, and the voltage applied to the second word line (WL2) and the second bit line (BL2) is zero. Therefore, hot electrons generated near the drain channel can be injected into the memory cell by means of hot electron injection.

When performing erase along the second word line (WL2) in FIG. 2, the voltage applied to the first word line (WL1) of the gate is zero, the voltage applied to the first bit line (BL1) of the source is zero, the voltage applied to the second bit line (BL2) is zero, and the voltage applied to the second word line (WL2) is a high voltage (V_{PP}). Therefore, electrons stored in the memory cell can be removed by means of Fowler-Nordheim tunneling (F-N tunneling) to accomplish the object of erasion.

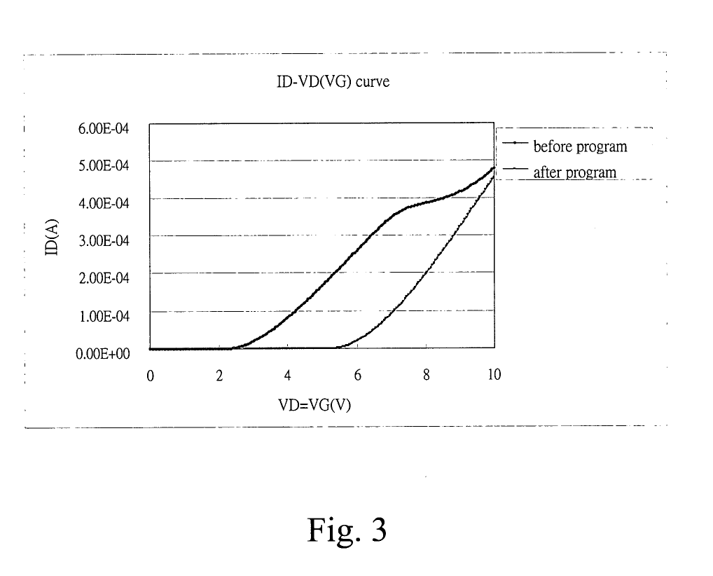

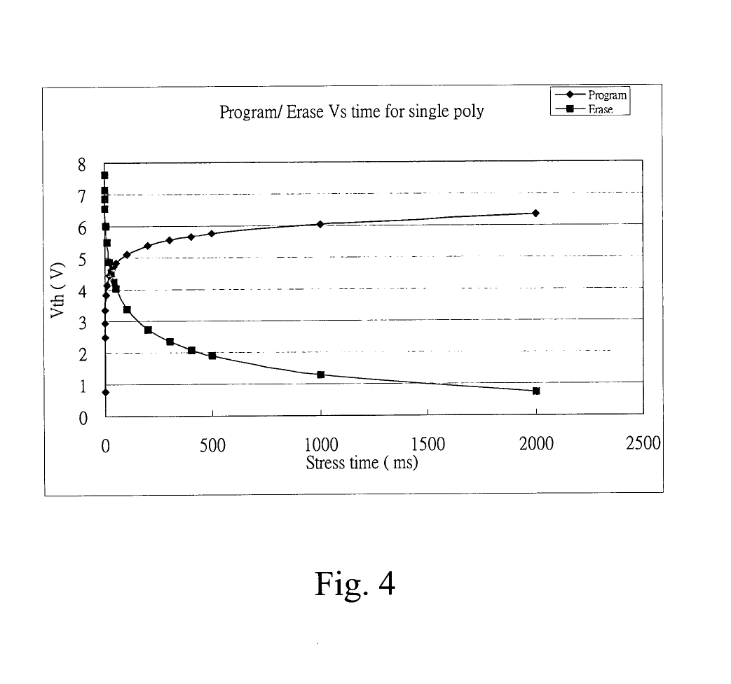

The present invention exemplifies with a single poly nonvolatile flash memory component fabricated by the conventional 0.5 um flat cell fabrication process. As compared to the size of a conventional single poly flash memory component, the size of the flash memory component of the present invention can be shrunk by about 30˜40% according to the same 0.5 um flat cell design rule. As shown in FIG. 3, after performing program, the threshold voltage of the memory component will rise notably, meaning logic “0” and “1” signals can be clearly discriminated after the flash memory component has been programmed. FIG. 4 is a program/erase versus time curve of a storage memory cell of the present invention. This embodiment not only applies to 0.5 um single poly nonvolatile flash memory components, but also applies to other double poly flash memory components.

To sum up, the present invention proposes a nonvolatile memory cell array having high-density memory cells, wherein the area of memory cell can be effectively shrunk, and the integration density of memory cell can also be effectively enhanced.

Although the present invention has been described with reference to the preferred embodiments thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

I claim:

1. A nonvolatile memory cell array formed by arranging a plurality of memory cells in array, said nonvolatile memory cell array comprising:
a plurality of bit lines for connecting a plurality of memory cells on transversal rows;
a plurality of word lines for connecting a plurality of memory cells on longitudinal columns; and
a plurality of storage memory cells, a combination of each of said word lines and each of said bit lines representing a specific one of said storage memory cells, each of said storage memory cells being composed of a capacitor and a transistor, the source of each of said transistors being electrically connected to a corresponding one of said word lines, the gate and drain of each of said transistors being series connected together to a corresponding one of said bit lines.

2. The nonvolatile memory cell array as claimed in claim 1, wherein when performing read to one of said storage memory cells, the voltage applied to said bit line of said transistor of said storage memory cell is a operation voltage VCC, the voltage applied to said word line is zero, the voltage applied to other word lines is the operation voltage VCC or floating, and the voltage applied to other bit lines is zero.

3. The nonvolatile memory cell array as claimed in claim 1, wherein when performing program to one of said storage memory cells, the voltage applied to said bit line of said transistor of said storage memory cell is a high voltage V_{PP}, the voltage applied to said word line is zero, the voltage applied to other word lines is floating, and the voltage applied to other bit lines is zero.

4. The nonvolatile memory cell array as claimed in claim 3, wherein the channel hot electron injection technique is made use of to accomplish write-in of data in said program mode.

5. The nonvolatile memory cell array as claimed in claim 1, wherein when performing erase along one of said word lines, the voltage applied to said bit lines of said transistors of said storage memory cells along said word line is zero, the voltage applied to said word line is a high voltage V_{PP}, and the voltage applied to other word lines is zero.

6. The nonvolatile memory cell array as claimed in claim 5, wherein the Fowler-Nordheim tunneling technique is made use of to accomplish erasion of data in said erase mode.
